(19) United States
(12) Patent Application Publication
(10) Pub. No.: US 2026/0002993 A1
(43) Pub. Date: Jan. 1, 2026

(54) PARAMETER ESTIMATION FOR VOLTAGE MEASUREMENTS IN NOISY ENVIRONMENTS

(71) Applicant: Hitachi Energy Ltd, Zurich (CH)

(72) Inventor: Mohsen ASOODAR, Solna (SE)

(21) Appl. No.: 19/131,328

(22) PCT Filed: Nov. 14, 2023
(86) PCT No.: PCT/EP2023/081750

§ 371 Date: May 20, 2025

(30) Foreign Application Priority Data
Nov. 30, 2022 (EP) 22210653.6

(51) Int. Cl. G01R 31/327; G01R 31/28

(52) U.S. Cl. CPC G01R 31/3274; G01R 31/2813

(57) ABSTRACT

A method for estimating an ON-state resistance of a semiconductor switch in an electric power converter is provided. The method comprises obtaining, from a measurement circuit, an ON-state voltage of the semiconductor switch. The method further comprises obtaining an ON-state current through the semiconductor switch. The method further comprises obtaining a selected frequency, extracting voltage harmonics of the selected frequency from the ON-state voltage, and extracting current harmonics of the selected frequency from the ON-state current. The method further comprises integrating the voltage harmonics over a period of time, to obtain an integrated voltage. The method further comprises integrating the current harmonics over the same period of time, to obtain an integrated current. The method further comprises determining an ON-state resistance estimate of the semiconductor switch based on the integrated voltage and the integrated current.

### TECHNICAL FIELD

The present disclosure relates generally to the field of electrical power systems. More specifically it relates to a method for parameter estimation in an electrical power system.

### BACKGROUND

Measurements are inevitably inaccurate. This is partly due to the measurement accuracy, but also due to noise. Measurement inaccuracies such as offsets can be corrected by comparing to a reference, however inaccuracies such as noise cannot be simply mitigated. One solution is to reduce noise at the cost of lowering the bandwidth (analog or digital), however, this would skew the measurements at the frequency of interest, manipulate their magnitude and complicate high frequency measurements. For linear time-invariant (LTI) systems, Kalman filtering and other recursive estimation algorithms have shown to be effective in reducing the effect of noise. However, such algorithms are only effective when a reasonable amount of noise is present. What counts as reasonable depends on the application and the required accuracies, but for condition monitoring of components where +99% accuracy is needed, even 3% noise in voltage and current measurements has shown to be too much.

### SUMMARY

It is therefore an object of the present invention to overcome at least some of the above-mentioned drawbacks, and to provide an estimation of parameters based on noisy measurements, in particular voltage and/or current measurements.

This and other objects are achieved by means of methods as defined in the appended independent claims. Other embodiments are defined by the dependent claims.

According to a first aspect of the present disclosure, a method for estimating an ON-state resistance of a semiconductor switch in an electric power converter is provided. The method comprises obtaining an ON-state voltage of the semiconductor switch from a measurement circuit. The method further comprises obtaining an ON-state current through the semiconductor switch. The method further comprises obtaining a selected frequency, extracting voltage harmonics of the selected frequency from the ON-state voltage, and extracting current harmonics of the selected frequency from the ON-state current. The method further comprises integrating the voltage harmonics over a period of time to obtain an integrated voltage. The method further comprises integrating the current harmonics over the same period of time to obtain an integrated current. The method further comprises determining an ON-state resistance estimate of the semiconductor switch based on the integrated voltage and the integrated current.

A converter may comprise a plurality of submodules connected in series, e.g. in one or more arms, such that if an arm of the converter has N submodules, the converter output voltage will have N+1 or 2N+1 levels (e.g. depending on whether submodules comprise half- or full-bridges, respectively), where each level is a voltage contribution for each step of the step-wise built output waveform for the converter (i.e. N levels of VSM plus zero, where VSM is a voltage contribution from a single submodule). Thus, typically, the more levels a converter has, the more a step-wise-built output waveform may approximate an AC waveform, for example.

Submodules of such converters may typically comprise capacitors connected to modulated switches, these electronic components being arranged in e.g. a half-bridge or full-bridge configuration. The switches may be modulated (e.g. by a converter control unit) in such a way as to switch the capacitors into and out of a contribution to a voltage output of the converter so as to build an output waveform in a stepwise fashion. The modulation scheme may be configured such that the output waveform approximates an AC waveform.

The ON-state is when the semiconductor switch is closed, i.e. ON. Therefore, the ON-state voltage is the voltage across the semiconductor switch when the semiconductor switch is closed. The ON-state current is the current through the semiconductor switch when the semiconductor switch is closed.

The ON-state voltage may be measured across the semiconductor switch. In a converter, the ON-state voltage measurement often has a small signal value (in the 0-4 V range) and is naturally in a noisy environment, the signal to noise ratio (SNR) may therefore be low. Depending on the design of the system, the noise could be at the same level as, or even higher than. the signal. The SNR may therefore be as low as a few percent (e.g. 5%), or as high as above 90%.

Further, the operating point of the converter may also affect the SNR. If the sensors are designed to capture nominal voltage and current levels, a decrease in load to, e.g., 10% of nominal current may lead to a decrease in the SNR, which is not because the noise grew, but because the signal is reduced.

For lower SNR values, it is difficult to extract a reliable signal value using conventional methods.

The ON-state current of the semiconductor switch may be measured at the switch. Alternatively, if the semiconductor switch is arranged in a submodule of the converter, the ON-state current may be estimated based on a measured current through the submodule and an obtained switching function of the switch. For example, the ON-state current may be estimated as:

$${i}_{O N} ( t ) = {i}_{arm} ( t ) \times s ( t ) = \hat{ι} sin ( ω t + {φ}_{i} ) \times s ( t )$$

Where î sin(ωt+φᵢ) is the current through the submodule, and s(t) is the switching pattern/function of the switch.

For example, the current through the submodule may be an arm or chain-link current in a multi-level modular converter, MMC. For a 2- or 3-level converter, an output current or load current may be measured and used for estimating the ON-state current.

In converters, the current through the submodule (e.g., arm current or load current) is often measured for other purposes. Therefore, this estimation may be made without additional sensors.

By integrating the voltage and the current, the signal values may increase over time, while the noise levels may not increase at the same rate. The proposed method may therefore increase the SNR artificially.

The period of time over which the signals are integrated may be in the range of 0.02-10 s. The longer the period of time, the more accurate the measurement may be. The integration time may be dependent on the switching frequency of the switch. For a higher switching frequency, a shorter period of time may be used, and for a lower switching frequency, a longer period of time may be used.

ON-state voltage may be a suitable parameter for condition monitoring of semiconductor devices (switches). A change in the ON-state voltage may typically be attributed to variation in the ON-state resistance. Hence, for condition monitoring, the ON-state resistance of the device/switch may be extracted. Since this resistance value is often quite small (in the mΩ range) accurate monitoring techniques are required.

With the present method, the resistance may be estimated based on measurements with improved SNR, which may provide a more reliable, and less noisy, estimate.

The resistance estimate may for example be estimated by dividing the integrated voltage with the integrated current.

The present method may provide a special parameter estimation technique in noisy environments. For example, the method may increase the accuracy of the resistance estimation, by minimizing the effect of the noise. The proposed method may be less sensitive to noise than traditional estimation methods, such as RLS (recursive least square) or Kalman filter.

The methods provided by the present disclosure may be implemented in a computer. For example, the methods may be executed or performed by a processor or a controller.

The method comprises obtaining a selected frequency. The method further comprises extracting voltage harmonics (or voltage harmonic components) of the selected frequency from the ON-state voltage. The method further comprises extracting current harmonics (or current harmonic components) of the selected frequency from the ON-state current. The method further comprises integrating the voltage harmonics over the period of time to obtain the integrated voltage. The method further comprises integrating the current harmonics over the period of time to obtain the integrated current. In the proposed methods, integrated components of certain frequencies are used to increase the signal to noise ratio (SNR) artificially. Integration without prior extraction of harmonics of a selected frequency corresponds to an integration of the direct current components of the voltage/current. However, many sensors are especially sensitive to offsets for DC measurements. For other frequencies, the sensors may provide only a little or no offset to the measurements. Therefore, extracting harmonics of a selected frequency prior to integration may further increase the accuracy of the resulting estimates.

The selected frequency may be any selected frequency. For example, the selected frequency may be the fundamental frequency (or any integer multiplied with the fundamental frequency) of a power grid to which the converter is connected. The fundamental frequency (or any multiple thereof) may be especially predictable/measurable.

According to some embodiments, the extracting voltage harmonics of the selected frequency may comprise multiplying the ON-state voltage with a vector rotating at the selected frequency. The extracting current harmonics of the selected frequency may comprise multiplying the ON-state current with a vector rotating at the selected frequency.

According to some embodiments, the method may further comprise obtaining a voltage offset of the obtained voltage. The method may further comprise obtaining a current offset of the obtained current. The method may further comprise adjusting the resistance estimate based on the voltage offset and the current offset.

As mentioned above, the sensors are often especially sensitive to offsets for DC values. Therefore, for DC estimates, the offset may be determined separately (e.g. using a self-correcting ADC) and removed from the voltage and/or current measurement prior to the estimation of the resistance. According to some embodiments, a method for determining a state of health of a semiconductor switch in an electric power converter may be provided.

The method may comprise determining an ON-state resistance estimate of the semiconductor switch in accordance with any of the above-described embodiments. The method may further comprise determining a state of health of the semiconductor switch based on the determined ON-state resistance estimate.

For example, the estimated resistance may be monitored over time, to detect changes in the resistance. The estimated resistance may be compared with an initial value of the resistance, to identify a change in the resistance. The estimated resistance may be compared with a threshold value, to detect when the resistance has reached a limit.

According to some embodiments, the converter may comprise a plurality of series-connected submodules. Each of the submodules may comprise a capacitor and a plurality of semiconductor switches arranged in a half-bridge or a full-bridge submodule topology. The semiconductor switch (mentioned in the method embodiments described above) may be one of the plurality of semiconductor switches of one of the series-connected submodules.

For example, the submodules may form part of a converter arm of a power converter.

According to some embodiments, the semiconductor switch may be one of a group of semiconductor switches arranged in a same position in the circuit topology of their respective submodule. The determining an ON-state resistance estimate may comprise determining an ON-state resistance estimate for each of the group of semiconductor switches. The determining a state of health may comprise determining, for the group of semiconductor switches, a group value of the estimated resistance. The determining a state of health may further comprise determining a deviation of the estimated resistance from the group value, for at least one semiconductor switch in the group. The determining a state of health may further comprise determining a state of health for the at least one semiconductor switch of the group based on the determined deviation for the semiconductor switch.

As used herein, the ‘topology’ of a circuit may be thought of as the relative electrical position of a component in a circuit, decoupled from any consideration of the physical position of said component. Thus, components having a same position in a same circuit topology may experience the same electrical behavior under the same electrical conditions.

The group value, which may be an average (e.g. mean, median) of the estimated resistance for each semiconductor switch in the group.

A ‘group’ is defined by as being a corresponding electrical component from each submodule, in the plurality of submodules, having a same position in the circuit topology of their respective submodule. For example, in submodules that all have a full-bridge submodule topology, the capacitor in each submodule will be arranged in a same position in the full-bridge submodule topology. Similarly, each of the plurality of semiconductor switches will have a position in the circuit topology such that switches in a same position in different submodules will experience a same electrical behavior (e.g. according to the modulation scheme for the converter).

Thus, as each electrical component in said group is experiencing the same electrical behavior, it can be assumed that the average power losses for each component in the group are the same, considering also that the plurality of submodules/electric storage units are connected in series such that current is evenly shared thereacross.

According to a second aspect of the present disclosure, a method for estimating a circuit parameter of a supercapacitor in an energy storage system is provided. The method comprises injecting a current having a selected frequency in the super capacitor. The method further comprises obtaining, from a measurement circuit, a voltage measured across the supercapacitor. The method further comprises extracting voltage harmonics of the selected frequency from the voltage and extracting current harmonics of the selected frequency from the injected current. The method further comprises integrating the voltage harmonics over a period of time, to obtain an integrated voltage. The method further comprises integrating the current harmonics over the same period of time, to obtain an integrated current. The method further comprises determining a circuit parameter estimate of the supercapacitor based on the integrated voltage and the integrated current.

An energy storage system (ESS) may comprise a plurality of energy storage units (ESUs) connected in series, e.g., in one or more strings, wherein each ESU may comprise a battery management system (BMS), which may also be referred to as an energy storage management system (ESMS), configured to balance the amounts of stored electrical energy between ESUs in a string. The supercapacitor of the second aspect of the present disclosure may be an ESU of an energy storage system.

The circuit parameter may for example be a capacitance, an equivalent series resistance (ESR) or a leakage resistance.

For the supercapacitors, the integration time may be different from the integration period of the first aspect above. For the supercapacitors, the current is injected, meaning that the frequency of the current and the time of the injection may be controlled. The dynamics of supercapacitor systems may typically be slow. Therefore, a longer integration time may be used. For high frequencies, e.g., in the range 50-1000 Hz, or more, the integration period may be in the range of seconds. For low frequencies, e.g., in the range 1-50 Hz, or less, the integration period may be in the range of seconds, minutes, or in some case hours.

Further, the integration time may be related to a magnitude of the injected current. For example, for a larger magnitude of the injected current, the integration time may be shorter, and vice versa.

As for the semiconductor switch described above, the voltage across a supercapacitor may have a small signal value in a noisy environment. The SNR may thus be low for measurements of the supercapacitor voltage. The method of the second aspect therefore provides the same solution as the method in the first aspect, but for a different device. It will be appreciated that similar advantages and explanations as provided above for the method of the first aspect may apply to the method of the second aspect. For brevity, not all of the explanations and advantages will be repeated for the second aspect.

The injected current has a selected frequency. The method further comprises extracting voltage harmonics of the selected frequency from the voltage. The method further comprised extracting current harmonics of the selected frequency from the injected current. The method further comprises integrating the voltage harmonics over the period of time to obtain the integrated voltage. The method further comprises integrating the current harmonics over the period of time to obtain the integrated current.

As discussed above, many sensors are sensitive to offsets for direct current measurements. At frequencies other than 0 Hz, the measurements may be less affected by offsets. Therefore, by extracting harmonic content of a selected frequency prior to integration, the integration may be based on more exact measurements, which may further increase the accuracy of the estimation.

According to some embodiments, the extracting voltage harmonics of the selected frequency may comprise multiplying the voltage with a vector rotating at the selected frequency. The extracting current harmonics of the selected frequency may comprise multiplying the injected current with a vector rotating at the selected frequency.

According to some embodiments, the method may further comprise obtaining a voltage offset of the obtained voltage. The method may further comprise obtaining a current offset of the obtained current. The method may further comprise adjusting the circuit parameter estimate based on the voltage offset and the current offset.

As described above for the first aspect of the present disclosure, many sensors are sensitive for direct current measurements. Such sensors often introduce measurement offsets for DC measurements. Integrating the measured signal values may correspond to an extraction and amplification of the direct current components of the signal. By obtaining (estimating, determining) the offsets of the measurements, and removing them prior to the estimation of the circuit parameter, the accuracy of the estimation may be further improved.

According to some embodiments, the method may further comprise obtaining current measurements of a current running through the supercapacitor. The current harmonics may be extracted from the current measurements.

The actual injected current, passing through the supercapacitor, may in some cases differ from the reference current, for example when using open loop current injection. Measuring the resulting (actual) current passing through the supercapacitor may therefore further improve the parameter estimation.

According to some embodiments, a method for determining a state of health of a supercapacitor in an energy storage system may be provided. The method may comprise determining a circuit parameter estimate of the supercapacitor in accordance with any of the above-described method embodiments of the second aspect. The method may further comprise determining a state of health of the supercapacitor based on the determined circuit parameter estimate.

As for the estimated resistance, described above, the estimated circuit parameter may be monitored over time, to detect changes in the resistance. The estimated circuit parameter may be compared with an initial value of the resistance, to identify a change in the resistance. The estimated circuit parameter may be compared with a threshold value, to detect when the resistance has reached a limit.

According to some embodiments, the supercapacitor may be one of a group of supercapacitors arranged in series.

For example, the plurality of supercapacitors may be a plurality of series-connected energy storage units (ESUs).

For example, the supercapacitor may be arranged as a DC link of a converter.

According to some embodiments, the determining a circuit parameter estimate may comprise determining a circuit parameter estimate for each of the group of supercapacitors arranged in series. The determining a state of health may comprise determining, for the group of supercapacitors a group value of the circuit parameter estimate. The determining a state of health may further comprise determining a deviation of the circuit parameter estimate from the group value, for at least one supercapacitor in the group. The determining a state of health may further comprise determining a state of health for the at least one supercapacitor of the group based on the determined deviation for the supercapacitor.

In a group of series-connected supercapacitors, each of the supercapacitors is subject to the same current. Thus, as each of the supercapacitors is experiencing the same electrical behavior, it can be assumed that the average power losses for each component in the group are the same, considering also that the plurality of ESUs are connected in series such that current is evenly shared thereacross.

During operation of an ESS, temperature-associated variations in electrical characteristics of the series-connected supercapacitors can be assumed to be substantially the same. A significant deviation of a component value for a circuit parameter from the group value can be attributed to poor health of the individual component having said deviating component value.

The methods of the first and second aspects of the present disclosure may be at least in part implemented in a control unit. For example, a control unit may comprise means for carrying out the method of any of the embodiments of the first aspect. For example, a control unit may comprise means for carrying out the method of any of the embodiments of the second aspect.

A converter may comprise a control unit comprising means for carrying out the method of any of the embodiments of the first aspect. An energy storage system may comprise a control unit comprising means for carrying out the method of any of the embodiments of the second aspect.

A power station may comprise a converter comprising a control unit comprising means for carrying out the method of any of the embodiments of the first aspect. A power station may comprise an energy storage system comprising a control unit comprising means for carrying out the method of any of the embodiments of the second aspect.

The methods of the first and/or second aspects may be provided as computer readable instructions. For example, a non-transitory computer-readable medium may comprise instructions which, when executed by a computer, may cause the computer to carry out the method of any of the embodiments of the first and/or second aspects.

It is noted that other embodiments using all possible combinations of features recited in the above-described embodiments may be envisaged. Thus, the present disclosure also relates to all possible combinations of features mentioned herein.

### BRIEF DESCRIPTION OF DRAWINGS

Exemplifying embodiments will now be described in more detail, with reference to the following appended drawings:

FIG. 1 schematically shows measurement circuit for a semiconductor switch;

FIG. 2 schematically shows an example converter coupled to an AC power grid, the converter having a plurality of series-connected submodules;

FIG. 3 schematically shows an example circuit topology for a submodule of a converter;

FIG. 4 is a flowchart illustrating a method for estimating an ON-state resistance of a semiconductor switch in an electric power converter, in accordance with some embodiments;

FIG. 5 is a flowchart illustrating a method for estimating a circuit parameter of a supercapacitor in an energy storage system, in accordance with some embodiments;

FIG. 6 schematically shows a supercapacitor; and

FIG. 7 schematically shows a group of supercapacitors arranged in series.

As illustrated in the figures, the sizes of the elements and regions may be exaggerated for illustrative purposes and, thus, are provided to illustrate the general structures of the embodiments. Like reference numerals refer to like elements throughout.

### DETAILED DESCRIPTION

Exemplifying embodiments will now be described more fully hereinafter with reference to the accompanying drawings in which currently preferred embodiments are shown. The invention may, however, be embodied in many different forms and should not be construed as limited to the embodiments set forth herein; rather, these embodiments are provided for thoroughness and completeness, and fully convey the scope of the invention to the skilled person.

The proposed solution may be suitable for LTI systems, or nonlinear systems that may be modelled linearly for certain operation points. In a stable LTI system, the relation between two state variables (or between the input and the output) may be represented in the Laplace domain as,

$$\frac{Y ( s )}{X ( s )} = H ( s ) = \frac{{a}_{0} + {a}_{1} s + … + {a}_{n} {s}^{n}}{{b}_{0} + {b}_{1} s + … + {b}_{n} {s}^{n}} \qquad ( 1 )$$

In the time domain solution of (1) for a stable system, the real components decay as time becomes infinitely large, leaving only the oscillatory (imaginary) components. Hence, in steady-state, for every angular frequency ω, H(s) may be replaced by H(jω) as,

$$\frac{Y ( j ω )}{X ( j ω )} = H ( j ω ) = \frac{{a}_{0} + {a}_{1} ( j ω ) + … + {{a}_{n} ( j ω )}^{n}}{{b}_{0} + {b}_{1} ( j ω ) + … + {{b}_{n} ( j ω )}^{n}} \qquad ( 2 )$$

In other words, the linear relation between X(jω) and Y(jω) may be identified by extracting the ω^{th} harmonic content from Y(jω) and X(jω), and then dividing the extracted ω^{th} harmonic contents of Y(jω) and X(jω).

This solution may be accurate for a very large data set, during which X(jω) and Y(jω) are in steady state. For such a solution a fast Fourier transform (FFT) may be used to derive the relations between X(jω) and Y(jω)).

However, if X(jω) and Y(jω) include noise, uncertainties, and/or change over time, the estimated value may differ depending on the window of data, the amount of noise, the load jumps, etc. Although this difference may be small, in certain applications, such as monitoring conditions, even 1% error in estimation is significant.

The present solution proposes a method for estimating

$$\frac{Y ( j ω )}{X ( j ω )} ,$$

based on the corresponding signals in the time domain y(t) and x(t). Harmonics of a selected frequency of each of the time domain signals are extracted and integrated. The present solution provides that division of the extracted and integrated harmonics may provide an estimate for

$$\frac{Y ( j ω )}{X ( j ω )} .$$

The methods according to the present disclosure, may artificially increase the value of the actual signal, while any frequency component that is not of the ω^{th} will not grow but remain in its oscillating state. For a long enough integration time, the effect of other harmonics on the integrated value of the ω^{th} frequency component may be negligible.

Mathematically, a proposal of the present disclosure is that,

$$\frac{\int y ( t ) \times {e}^{- j ω t} d t}{\int x ( t ) \times {e}^{- j ω t} d t} = \hat{H} ( j ω ) , \qquad ( 3 )$$

may be a good estimate of H(jω).

Different ways of extracting the phasor values X(jω) and Y(jω) exist. One proposal is to multiply the signal with a rotating vector with arbitrary initial phase, such that,

$${x}_{d} = x ( t ) \times cos ( ω t ) \qquad ( 4 )$$

$${x}_{q} = x ( t ) \times sin ( ω t )$$

Due to the single-phase nature of x_{d} and x_{q}, both parameters comprise a dc component and a component at 2ωt. As explained earlier, any non-dc component in (4) is not a concern when applying the proposed technique. Similar equations can be written for y(t) as well, to give,

$${y}_{d} = y ( t ) \times cos ( ω t ) \qquad ( 5 )$$

$${y}_{q} = y ( t ) \times sin ( ω t )$$

x(t) and y(t) can be expanded as follows,

$$x ( t ) = {x}_{d c} + {a}_{x , ω} sin ( ω t + {φ}_{x , ω} ) + {h}_{x} \qquad ( 6 )$$

$$y ( t ) = {y}_{d c} + {a}_{y , ω} sin ( ω t + {φ}_{y , ω} ) + {h}_{y}$$

where hₓ and h_{y} represent the harmonic content of x(t) and y(t) respectively.

Substituting of (4) with x(t) of (6) yields,

$${x}_{d} = ( {x}_{d c} + {a}_{x , ω} sin ( ω t + {φ}_{x , ω} ) + {h}_{x} ) \times cos ( ω t ) = \frac{{a}_{x , ω}}{2} sin ( {φ}_{x , ω} ) + ( {x}_{d c} \times cos ( ω t ) + \frac{{a}_{x , ω}}{2} sin ( 2 ω t + {φ}_{x , ω} ) + {h}_{x} \times cos ( ω t ) ) \qquad ( 7 )$$

$${x}_{q} = ( {x}_{d c} + {a}_{x , ω} sin ( ω t + {φ}_{x , ω} ) + {h}_{x} ) \times sin ( ω t ) = \frac{{a}_{x , ω}}{2} cos ( {φ}_{x , ω} ) + ( {x}_{d c} \times sin ( ω t ) + \frac{{a}_{x , ω}}{2} cos ( 2 ωt + {φ}_{x , ω} ) + {h}_{x} \times sin ( ω t ) )$$

As per definition, hₓ×cos(ωt) and hₓ×sin(ωt) contain no dc components. Hence, the only dc component of (7) are

$$\frac{{a}_{x , ω}}{2} sin ( {φ}_{x , ω} )$$

for x_{d} and

$$\frac{{a}_{x , ω}}{2} cos ( {φ}_{x , ω} )$$

for x_{q}. Integrating (7) over a period T results in

$${x}_{d , IntT} ( t ) = {\int }_{t = 0}^{t = T} {x}_{d} ( t ) = {\int }_{t = 0}^{t = T} x ( t ) \times cos ( ω t ) = T \frac{{a}_{x , ω}}{2} sin ( {φ}_{x , ω} ) + {\int }_{t = 0}^{t = T} ( {x}_{dc} \times cos ( ω t ) + \frac{{a}_{x , ω}}{2} sin ( 2 ω t + {φ}_{x , ω} ) + {h}_{x} \times cos ( ω t ) ) \qquad ( 8 )$$

$${x}_{q , IntT} ( t ) = {\int }_{t = 0}^{t = T} {x}_{q} ( t ) = {\int }_{t = 0}^{t = T} x ( t ) \times sin ( ω t ) = T \frac{{a}_{x , ω}}{2} cos ( {φ}_{x , ω} ) + {\int }_{t = 0}^{t = T} ( {x}_{dc} \times sin ( ω t ) + \frac{{a}_{x , ω}}{2} cos ( 2 ω t + {φ}_{x , ω} ) + {h}_{x} \times sin ( ω t ) )$$

Both x_{d,IntT}(t) and x_{q,IntT}(t) comprise a dc term and an oscillatory term. The dc term of x_{d,IntT}(t) and x_{q,IntT}(t) grows over time as a result of the integration while the oscillatory terms remain oscillatory. Hence, for a large duration of integration, the oscillatory terms x_{d,IntT}(t) and x_{q,IntT}(t) become negligible compared to the integrated dc terms of the same.

That is,

$${lim}_{T \to ∞} {x}_{d , IntT} ( t ) = T \frac{{a}_{x , ω}}{2} sin ( {φ}_{x , ω} ) \qquad ( 9 )$$

$${lim}_{T \to ∞} {x}_{q , IntT} ( t ) = T \frac{{a}_{x , ω}}{2} cos ( {φ}_{x , ω} )$$

Consequently, the vector magnitude of Xᵢₙₜ(jω) can be represented as

$${lim}_{T \to ∞} {\vert {X}_{intT} ( j ω ) \vert}^{2} = {( {lim}_{T \to ∞} {x}_{d , IntT} ( t ) )}^{2} + {( {lim}_{T \to ∞} {x}_{q , IntT} ( t ) )}^{2} ∼ {( T \frac{{a}_{x , ω}}{2} )}^{2} \qquad ( 10 )$$

Similarly, the vector magnitude of Yᵢₙₜ(jω) can be represented as

$${lim}_{T \to ∞} {\vert {Y}_{intT} ( j ω ) \vert}^{2} = {( {lim}_{T \to ∞} {y}_{d , IntT} ( t ) )}^{2} + {( {lim}_{T \to ∞} {y}_{q , IntT} ( t ) )}^{2} ∼ {( T \frac{{a}_{y , ω}}{2} )}^{2} \qquad ( 11 )$$

Finally, Hᵢₙₜ(jω) becomes

$${lim}_{T \to ∞} {\vert {H}_{intT} ( j ω ) \vert}^{2} = {lim}_{T \to ∞} \frac{{\vert {Y}_{intT} ( j ω ) \vert}^{2}}{{\vert {X}_{intT} ( j ω ) \vert}^{2}} = \frac{{( T \frac{{a}_{y , ω}}{2} )}^{2}}{{( T \frac{{a}_{x , ω}}{2} )}^{2}} = {( \frac{{a}_{y , ω}}{{a}_{x , ω}} )}^{2} ∼ \frac{{\vert Y ( j ω ) \vert}^{2}}{{\vert X ( j ω ) \vert}^{2}} = {\vert H ( j ω ) \vert}^{2} \qquad ( 12 )$$

In other words

$${lim}_{T \to ∞} {\vert {H}_{intT} ( j ω ) \vert}^{2}$$

is used to estimate |H(jω)|² but with the advantage of artificially increasing the SNR of the measured x(t) and y(t) at the frequency ω.

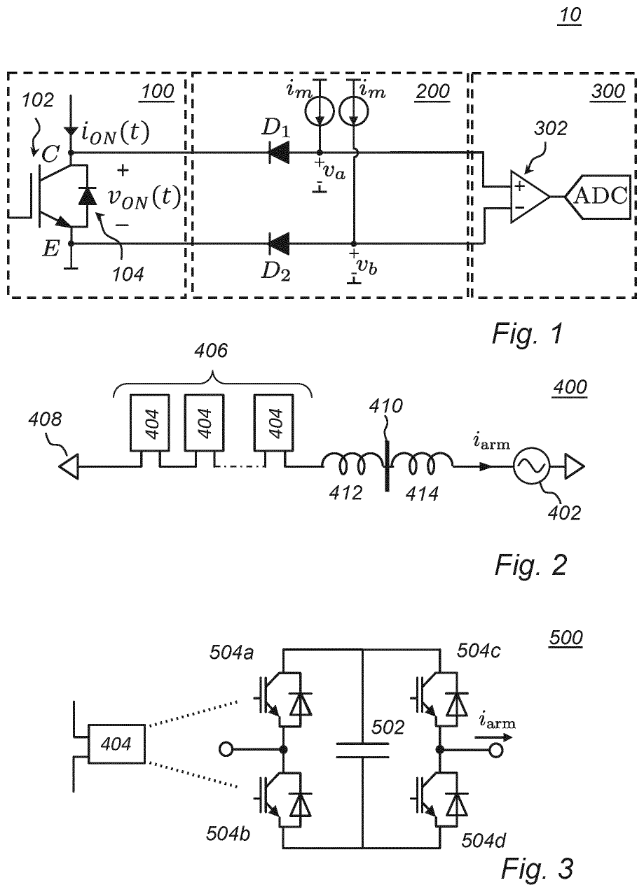

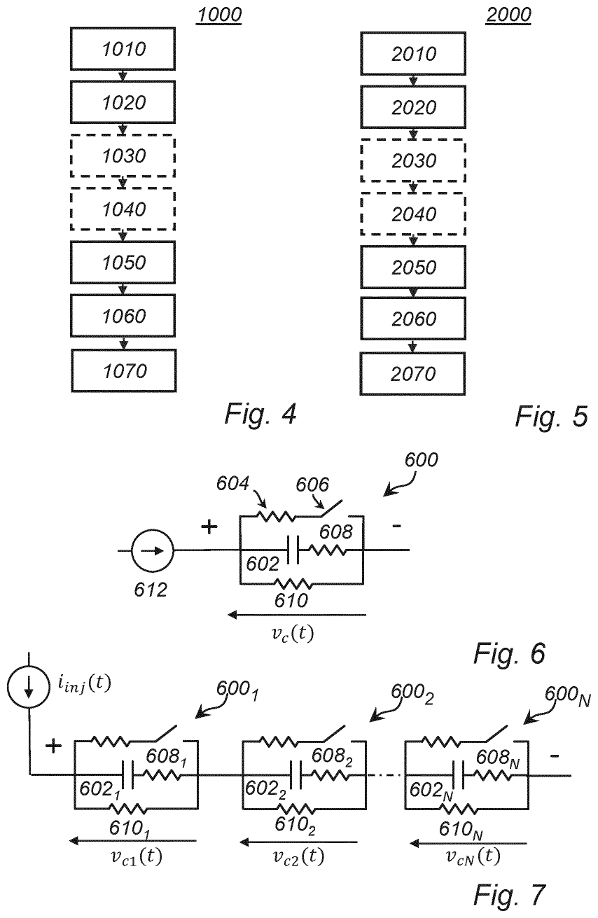

With reference to FIGS. 1 and 4, a method for estimating an ON-state resistance of a semiconductor switch in an electric power converter, in accordance with some embodiments, will be described.

FIG. 1 is a circuit diagram illustrating a measurement circuit 10 for online measurement of ON-state voltage of a semiconductor device 100. The semiconductor device 100 may be referred to as a device under test (DUT 100). The measurement circuit 10 comprises the semiconductor device (switch) 100, including a transistor 102 and a diode 104. An ON-state current i_{ON}(t) passes through the semiconductor switch 100, when in the ON-state. An ON-state voltage v_{ON}(t) can be measured across the semiconductor switch 100, when in the ON-state, by the measurement circuit 10.

The measurement circuit 10 also includes a protection circuit 200. The protection circuit allows low voltages to pass through but blocks high voltages on the DUT. In the OFF-state, the voltage across the semiconductor switch 100 may be very high. The protection circuit 200 protects the sensors in the sensing circuit 300 from such high voltages.

In FIG. 1, the sensing circuit 300 is an operational amplifier 302 and an analog-to-digital converter ADC for recording the measurements. In general, any differential or single ended measurement circuit, including any passive or active filtering circuit, may be used for the sensing circuit.

FIG. 4 is a flowchart illustrating a method 1000 for estimating an ON-state resistance of a semiconductor switch in an electric power converter. The method 1000 may for example be used to estimate the ON-state resistance of the semiconductor switch 100 illustrated in FIG. 1.

The method 1000 comprises obtaining, at step 1010, from a measurement circuit 10, an ON-state voltage v_{ON}(t) of the semiconductor switch 100. At step 1020, an ON-state current i_{ON}(t), through the semiconductor switch 100, is obtained. The method 1000 further comprises the optional steps 1030 and 1040. At the optional step 1030, voltage harmonics of an obtained selected frequency are extracted from the ON-state voltage v_{ON}(t). At the optional step 1040, current harmonics of the obtained selected frequency are extracted from the ON-state current i_{ON}(t).

Steps 1050 and 1060 are integration steps.

If the optional steps 1030 and 1040 are not present, the ON-state voltage v_{ON}(t) is integrated over a period of time T at step 1050, the ON-state current i_{ON}(t) is integrated over the period of time T at step 1060.

If the optional steps 1030 and 1040 are present, the extracted voltage harmonics are integrated over a period of time T at step 1050 and the extracted current harmonics are integrated over the period of time T at step 1060.

At step 1070, the resistance is estimated based on the results of the integrations from steps 1050 and 1060.

At step 1070, an obtained offset of the ON-state voltage measurement v_{ON}(t) and/or the ON-state current measurement i_{ON}(t) may be removed prior to the estimation of the resistance.

The estimated resistance may be used, in an optional further step (not depicted), to estimate a state of health of the semiconductor switch 100.

FIG. 2 is an illustration of a converter 400 coupled to an AC power grid 402. The illustrated converter 400 has only one arm 406, which may also be referred to as a ‘chain link’, although it will be appreciated that the converter may have more arms. Specifically, the converter 400 of FIG. 2 is a single phase modular multilevel converter.

The converter 400 is grounded at grounding point 408 and is coupled to the AC power grid 402 via a point of common coupling 410, which may be a busbar or a similar component. The converter 400 may further comprise an inductor 412 or the converter 400 may have innate inductance that can be represented as an inductor 412. The inductance of the power grid 402 may be represented by an inductor 414.

A converter 10 such as that shown in FIG. 2 may be controlled so as to convert electrical energy between DC and AC, for example. Thus, the converter may be a power converter suitable for HVDC applications. Examples sources of such DC electrical energy include solar panels, battery/capacitor banks (i.e. energy storage systems) and the like.

As illustrated in FIG. 2, the converter 10 comprises a plurality of submodules 404 arranged in series.

FIG. 3 schematically shows an example circuit topology 500 (or simply ‘topology 500’) for a submodule of a converter such as the submodules 404 of the converter 10 shown in FIG. 2.

As illustrated in FIG. 3, the circuit topology 500 of the submodule 404 may be a full-bridge submodule topology comprising a capacitor 502 and a plurality of semiconductor switches 504a, 504b, 504c, 504d (collectively ‘semiconductor switches 504’ or simply ‘switches 1504’). The semiconductor switches 504 may be equivalent to the semiconductor switch 100 described above with reference to FIG. 1. Specifically, the method 1000 described above with reference to FIG. 4 may be applied to any one of the semiconductor switches 504.

According to this topology 100, current iₐᵣₘ may enter the circuit between the connections of switches 504a and 504b and exit the circuit between the connections of switches 504c and 504d. The current iₐᵣₘ may be a current flowing through the plurality of series-connected submodules 404, such that the same current (iₐᵣₘ) may flow through all of the submodules 404 in the plurality of submodules (e.g., the arm 406 of the converter 10 shown in FIG. 2).

The terminals of the capacitor 502 may be connected between the connections of switches 504a and 504c and switches 504b and 504d. Thus, by controlling the switching of the switches 504 (i.e., their on/off state), the direction of current flow across the capacitor 502 can be controlled.

The manner in which the switches 504 are controlled may be referred to as a modulation scheme, e.g., according to a demand on/from the AC power grid 402. The switches 504 of each submodule 404 may be controlled using a same modulation scheme or different modulation schemes, for example with a predetermined delay (or phase difference) between the modulation scheme of different submodules 404.

An example of a modulation scheme may be a phase shifted carrier (PSC) modulation with pulse-width modulation (PWM). The particulars of converter modulation are outside of the scope of the present disclosure. However, a PSC-PWM modulation is an example of a modulation scheme that conforms to an assumption of even power losses across the components of different submodules 404 having a same position in the circuit topology 500.

In the method 1000, the ON-state current i_{ON}(t), through the semiconductor switch 100, 504, may be obtained by direct measurement. Alternatively, the ON-state current i_{ON}(t), may be estimated based on a measured current through a submodule 404 in which the semiconductor switch 100 is arranged, such as the arm current iₐᵣₘ.

Further, the above method 1000 may be applied to a group of semiconductor switches in arranged in a same position in the circuit topology of their respective submodule. For example, the method may be used to estimate the ON-state resistance of each of the top left semiconductor switches 504a in a plurality of series-connected submodules 404. The method 1000 may further comprise determining a group value of the estimated resistance, such as a mean or a median of the estimated resistances. The method 1000 may further comprise determining a deviation of the estimated resistance from the group value for at least one semiconductor switch 504a in the group. As the semiconductor switches 504a are initially substantially identical, and subject to the same current and a similar switching behavior, the resistance should theoretically change in the same way over time. Any deviation from the group value could then be attributed to a deterioration of the semiconductor switch in question. The method 1000 may further comprise determining a state of health for the semiconductor switch having a deviating value based on the determined deviation.

Returning to the general mathematical description provided above, and using the notation of FIGS. 1-3, during the ON-state of the device 100, the voltage v_{ON}(t) of the device 100 may be described as

$${v}_{ON} ( t ) = {R}_{ON} ( t ) {i}_{ON} ( t ) \qquad ( 13 )$$

i_{ON}(t) is the current passing through the device 100 as shown in FIG. 1. For an arbitrary device in a full-bridge, the current i_{ON}(t) can be defined as,

$${i}_{ON} ( t ) = {i}_{arm} \times s ( t ) = \hat{ι} sin ( ω t + {φ}_{i} ) \times s ( t ) \qquad ( 14 )$$

Where the s(t) is the switching function. For a phase shifted carrier pulse width modulation scheme (PSC-PWM), s(t) can be mathematically described as

$$s ( t ) = 0.5 + m sin ( ω t + {φ}_{s} ) + {h}_{s} ( t ) \qquad ( 15 )$$

Where m is the modulation index and hₛ(t) is the sum of all harmonic content. The switching function is a series of 0 and 1 signals. 1 representing a turn-ON and 0 representing a turn-OFF. Regardless of what modulation scheme is used, s(t) will have the dc component 0.5, a fundamental frequency component, and other harmonics hₛ(t). hₛ(t) includes integer multiple harmonics and interharmonics. Regardless of the modulation scheme, the 0.5 dc value will always be there because the sum of the upper and lower switch functions in a half bridge is 1 p.u.

In case the deadtime between the upper and lower switch is significantly large, the dc value in s(t) will not be 0.5. In that case, it may be better to measure the actual value from the switching pattern online rather than assuming the 0.5. In either case, the general proposed technique is still valid. Also, given the very short time of the deadtime compared to the actual on and off states, the error of assuming 0.5 may be far below 1%.

Substituting i_{ON}(t) in equation (13) with (14) and (15) yields

$${v}_{ON} ( t ) = {R}_{ON} \hat{ι} sin ( ω t + {φ}_{i} ) \times ( 0.5 + m sin ( ω t + {φ}_{s} ) + {h}_{s} ( t ) ) = \frac{{R}_{ON}}{2} \hat{ι} sin ( ω t + {φ}_{i} ) + ( \frac{{R}_{ON} m \hat{ι}}{2} ( cos ( {φ}_{i} - {φ}_{s} ) - cos ( 2 ω t + {φ}_{i} + {φ}_{s} ) ) ) + {R}_{ON} \hat{ι} sin ( ω t + {φ}_{i} ) {h}_{s} ( t ) \qquad ( 16 )$$

The only term that ends up with fundamental frequency is

$$\frac{{R}_{ON}}{2} \hat{ι} sin ( ω t + {φ}_{i} ) .$$

This is the term of interest. v_{ON}(t) and i_{ON}(t) represent x(t) and y(t) in equation (3) above. Hence, the parameter R can be estimated by extracting

$$\frac{{R}_{ON}}{2} \hat{ι}$$

from equation (16) and î from the arm current iₐᵣₘ. The arm current is often mostly comprised of a fundamental component, while v_{ON} may require longer integration to reduce the effect of noise and harmonics.

For estimating the R_{ON} value, a selected frequency component, such as the fundamental frequency component, or the DC component can be analysed. For the DC component, it is sufficient integrate the v_{ON} and i_{ON} as follows

$$\int \vert {v}_{ON} ( t ) \vert dt = \int \vert {R}_{ON} {i}_{ON} ( t ) \vert dt \qquad ( 17 )$$

$$or$$

$${R}_{ON} = \frac{\int \vert {v}_{ON} ( t ) \vert dt}{\int \vert {i}_{ON} ( t ) \vert dt}$$

With reference to FIGS. 5 to 7, a method for estimating a circuit parameter of a supercapacitor in an energy storage system, in accordance with some embodiments, will be described.

FIG. 6 schematically shows a single supercapacitor cell 600 equipped with a balancing circuit comprising a switch 606 and a balancing resistor 604. The voltage balancing circuit 604, 606 may provide equal voltage sharing between series-connected supercapacitor cells in steady state.

In FIG. 6, the supercapacitor cell is modeled by a supercapacitor 602, an equivalent series resistance 608 a leakage resistance 610. The current source represents the controlled current iᵢₙⱼ injected into the supercapacitor cell 600.

FIG. 5 is a flowchart illustrating a method 2000 for estimating a circuit parameter of a supercapacitor in an energy storage system. The method 2000 may for example be used to estimate the capacitance 602, the leakage resistance 610 or the ESR 608 of the supercapacitor 600 illustrated in FIG. 5.

The method 2000 comprises injecting, at step 2010, a current iᵢₙⱼ(t) in the supercapacitor 600. At step 2020, a voltage v_{c}(t) measured across the supercapacitor is obtained from a measurement circuit (not depicted).

The method 2000 further comprises the optional steps 2030 and 2040. In embodiments including the optional steps 2030 and 2040, the injected current iᵢₙⱼ(t) has a selected frequency ω.

At the optional step 2030, voltage harmonics of the selected frequency ω are extracted from the voltage v_{c}(t). At the optional step 2040, current harmonics of the selected frequency ω are extracted from the injected current iᵢₙⱼ(t). The current harmonics may be extracted from the injected current reference or from a measurement of the actual injected current.

Steps 2050 and 2060 are integration steps.

If the optional steps 2030 and 2040 are not present, the voltage v_{c}(t) is integrated over a period of time T at step 2050, and the injected current iᵢₙⱼ(t) is integrated over the period of time T at step 2060.

If the optional steps 2030 and 2040 are present, the extracted voltage harmonics are integrated over a period of time T at step 2050 and the extracted current harmonics are integrated over the period of time T at step 2060.

At step 2070, the circuit parameter 602, 608, 610 is estimated based on the results of the integrations from steps 2050 and 2060.

At step 2070, an obtained offset of the voltage measurement v_{c}(t) and/or the current measurement iᵢₙⱼ(t) may be removed prior to the estimation of the circuit parameter.

The estimated circuit parameter(s) may be used, in an optional further step (not depicted), to estimate a state of health of the supercapacitor 600.

FIG. 7 schematically shows a plurality of series-connected supercapacitor cells 600₁, 600₂, 600_{N}. In an ESS, several supercapacitors are series-connected in order to achieve higher voltage capability.

The method 2000 described above may be applied to each of the supercapacitors 600₁, 600₂, 600_{N}, to estimate a circuit parameter of each of the supercapacitors 600₁, 600₂, 600_{N}, such as the capacitances 602₁, 602₂, 602_{N}, the ESRs 608₁, 608₂, 608_{N}, or the leakage resistances 610₁, 610₂, 610_{N}.

The method 2000 may further comprise determining a group value of the circuit parameter estimate, such as a mean or a median of the circuit parameter estimates of each of the supercapacitors 600₁, 600₂, 600_{N}.

The method 2000 may further comprise determining or detecting a deviation of the circuit parameter estimate from the group value for at least one of the of the supercapacitors 600₁, 600₂, 600_{N}. As the of the supercapacitors 600₁, 600₂, 600_{N} are initially substantially identical, and subject to the same current, the circuit parameters should theoretically change in the same way over time. Any deviation from the group value could then be attributed to a deterioration of the supercapacitor in question. The method 2000 may further comprise determining a state of health for the supercapacitor having a deviating value based on the determined deviation.

The person skilled in the art realizes that the present invention by no means is limited to the preferred embodiments described above. On the contrary, many modifications and variations are possible within the scope of the appended claims.

Although features and elements are described above in particular combinations, each feature or element can be used alone without the other features and elements or in various combinations with or without other features and elements.

Additionally, variations to the disclosed embodiments can be understood and effected by the skilled person in practicing the claimed invention, from a study of the drawings, the disclosure, and the appended claims. In the claims, the word “comprising” does not exclude other elements, and the indefinite article “a” or “an” does not exclude a plurality. The mere fact that certain features are recited in mutually different dependent claims does not indicate that a combination of these features cannot be used to advantage.

### ITEMIZED LIST OF EMBODIMENTS

1. A method (1000) for estimating an ON-state resistance of a semiconductor switch (100) in an electric power converter, the method comprising:
   obtaining (1010), from a measurement circuit, an ON-state voltage (v_{ON}(t)) of the semiconductor switch;
   obtaining (1020) an ON-state current (i_{ON}(t)) through the semiconductor switch;
   integrating (1050) the ON-state voltage over a period of time (T), to obtain an integrated voltage;
   integrating (1060) the ON-state current over the same period of time (T), to obtain an integrated current;
   determining (1070) an ON-state resistance estimate of the semiconductor switch based on the integrated voltage and the integrated current.
2. The method of item 1, further comprising:
   obtaining a selected frequency (ω);
   extracting (1030) voltage harmonics of the selected frequency from the ON-state voltage;
   extracting (1040) current harmonics of the selected frequency from the ON-state current; wherein
   said integrating the ON-state voltage comprises integrating the voltage harmonics over the period of time to obtain the integrated voltage; and
   said integrating the ON-state current comprises integrating the current harmonics over the period of time to obtain the integrated current.
3. The method of item 2, wherein:
   said extracting voltage harmonics of the selected frequency comprises multiplying the ON-state voltage with a vector rotating at the selected frequency; and
   said extracting current harmonics of the selected frequency comprises multiplying the ON-state current with a vector rotating at the selected frequency.
4. The method of item 1, further comprising:
   obtaining a voltage offset of the obtained voltage;
   obtaining a current offset of the obtained current; and
   adjusting the resistance estimate based on the voltage offset and the current offset.
5. A method for determining a state of health of a semiconductor switch in an electric power converter, the method comprising:
   determining an ON-state resistance estimate of the semiconductor switch in accordance with any of the preceding items; and
   determining a state of health of the semiconductor switch based on the determined ON-state resistance estimate.
6. The method of any of the preceding items, wherein:
   said converter comprises a plurality of series-connected submodules (404), each comprising a capacitor (502) and a plurality of semiconductor switches (504a-d) arranged in a half-bridge or a full-bridge submodule topology; and
   said semiconductor switch is one of the plurality of semiconductor switches of one of the series-connected submodules.
7. The method of item 6 when dependent on item 5, wherein said semiconductor switch is one of a group of semiconductor switches arranged in a same position in the circuit topology of their respective submodule, wherein:
   the determining an ON-state resistance estimate comprises determining an ON-state resistance estimate for each of the group of semiconductor switches; and
   the determining a state of health comprises:
      determining, for the group of semiconductor switches, a group value of the estimated resistance;
      determining a deviation of the estimated resistance from the group value, for at least one semiconductor switch in the group; and
      determining a state of health for said at least one semiconductor switch of the group based on the determined deviation for the semiconductor switch.
8. A method (2000) for estimating a circuit parameter of a supercapacitor (600) in an energy storage system, the method comprising:
   injecting (2010) a current (iᵢₙⱼ(t)) in the supercapacitor;
   obtaining (2020), from a measurement circuit, a voltage (v_{c}(t)) measured across the supercapacitor;
   integrating (2050) the voltage over a period of time (T), to obtain an integrated voltage;
   integrating (2060) the injected current over the same period of time (T), to obtain an integrated current;
   determining (2070) a circuit parameter (602, 608, 610) estimate of the supercapacitor based on the integrated voltage and the integrated current.
9. The method of item 8, wherein the injected current has a selected frequency (ω), the method further comprising:
   extracting (2030) voltage harmonics of the selected frequency from the voltage; and
   extracting (2040) current harmonics of the selected frequency from the injected current; wherein
   said integrating the voltage comprises integrating the voltage harmonics over the period of time to obtain the integrated voltage; and
   said integrating the current comprises integrating the current harmonics over the period of time to obtain the integrated current.
10. The method of item 9, wherein:
   said extracting voltage harmonics of the selected frequency comprises multiplying the voltage with a vector rotating at the selected frequency; and
   said extracting current harmonics of the selected frequency comprises multiplying the injected current with a vector rotating at the selected frequency.
11. The method of item 8, further comprising:
   obtaining a voltage offset of the obtained voltage;
   obtaining a current offset of the obtained current; and
   adjusting the circuit parameter estimate based on the voltage offset and the current offset.
12. The method of any of items 8-11, further comprising:
   obtaining current measurements of a current running through the supercapacitor;
   wherein said integrating the injected current comprises integrating the current measurements to obtain the integrated current.
13. A method for determining a state of health of a supercapacitor in an energy storage system, the method comprising:
   determining a circuit parameter estimate of the supercapacitor in accordance with any of items 8-12; and
   determining a state of health of the supercapacitor based on the determined circuit parameter estimate.
14. The method of any of items 8-13, wherein said supercapacitor is one of a group of supercapacitors (600₁, 600₂, 600_{N}) arranged in series.
15. The method of item 14, when dependent on item 13, wherein:
   the determining a circuit parameter estimate comprises determining a circuit parameter estimate for each of the group of supercapacitors arranged in series; and
   the determining a state of health comprises:
      determining, for the group of supercapacitors a group value of the circuit parameter estimate;
      determining a deviation of the circuit parameter estimate from the group value, for at least one supercapacitor in the group; and
      determining a state of health for said at least one supercapacitor of the group based on the determined deviation for the supercapacitor.

1. A computer-implemented method for estimating an ON-state resistance of a semiconductor switch in an electric power converter, the method comprising:
obtaining, from a measurement circuit, an ON-state voltage of the semiconductor switch;
obtaining an ON-state current through the semiconductor switch;
obtaining a selected frequency;
extracting voltage harmonics of the selected frequency from the ON-state voltage;
extracting current harmonics of the selected frequency from the ON-state current;
integrating the voltage harmonics over a period of time, to obtain an integrated voltage;
integrating the current harmonics over the same period of time, to obtain an integrated current;
determining an ON-state resistance estimate of the semiconductor switch based on the integrated voltage and the integrated current.

2. The method of claim 1, wherein:
said extracting voltage harmonics of the selected frequency comprises multiplying the ON-state voltage with a vector rotating at the selected frequency; and
said extracting current harmonics of the selected frequency comprises multiplying the ON-state current with a vector rotating at the selected frequency.

3. A computer-implemented method for determining a state of health of a semiconductor switch in an electric power converter, the method comprising:
determining an ON-state resistance estimate of the semiconductor switch in accordance with any of the preceding claims; and
determining a state of health of the semiconductor switch based on the determined ON-state resistance estimate.

4. The method of claim 3, wherein:
said converter comprises a plurality of series-connected submodules, each comprising a capacitor and a plurality of semiconductor switches arranged in a half-bridge or a full-bridge submodule topology; and
said semiconductor switch is one of the plurality of semiconductor switches of one of the series-connected submodules.

5. The method of claim 4, wherein said semiconductor switch is one of a group of semiconductor switches arranged in a same position in the circuit topology of their respective submodule, wherein:
the determining an ON-state resistance estimate comprises determining an ON-state resistance estimate for each of the group of semiconductor switches; and
the determining a state of health comprises:
determining, for the group of semiconductor switches, a group value of the estimated resistance;
determining a deviation of the estimated resistance from the group value, for at least one semiconductor switch in the group; and
determining a state of health for said at least one semiconductor switch of the group based on the determined deviation for the semiconductor switch.

6. A computer-implemented method for estimating a circuit parameter of a supercapacitor in an energy storage system, the method comprising:
injecting a current having a selected frequency in the supercapacitor;
obtaining, from a measurement circuit, a voltage measured across the supercapacitor;
extracting voltage harmonics of the selected frequency from the voltage; and
extracting current harmonics of the selected frequency from the injected current;
integrating the voltage harmonics over a period of time, to obtain an integrated voltage;
integrating the current harmonics over the same period of time, to obtain an integrated current;
determining a circuit parameter estimate of the supercapacitor based on the integrated voltage and the integrated current.

7. The method of claim 6, wherein:
said extracting voltage harmonics of the selected frequency comprises multiplying the voltage with a vector rotating at the selected frequency; and
said extracting current harmonics of the selected frequency comprises multiplying the injected current with a vector rotating at the selected frequency.

8. The method of claim 6, further comprising:
obtaining current measurements of a current running through the supercapacitor;
wherein said current harmonics are extracted from the current measurements.

9. A computer-implemented method for determining a state of health of a supercapacitor in an energy storage system, the method comprising:
determining a circuit parameter estimate of the supercapacitor in accordance with claim 6; and
determining a state of health of the supercapacitor based on the determined circuit parameter estimate.

10. The method of claim 9, wherein said supercapacitor is one of a group of supercapacitors arranged in series.

11. The method of claim 10, wherein:
the determining a circuit parameter estimate comprises determining a circuit parameter estimate for each of the group of supercapacitors arranged in series; and
the determining a state of health comprises:
determining, for the group of supercapacitors a group value of the circuit parameter estimate;
determining a deviation of the circuit parameter estimate from the group value, for at least one supercapacitor in the group; and
determining a state of health for said at least one supercapacitor of the group based on the determined deviation for the supercapacitor.

12. The method of claim 6, wherein said supercapacitor is arranged on a DC link of a converter.

13. A control unit comprising means for carrying out the method according to claim 1.

14. A control unit comprising means for carrying out the method according to claim 6.

15. A computer-readable medium comprising instructions which, when executed by a computer, cause the computer to carry out the method according to claim 1.

16. The method of claim 1, wherein:
said converter comprises a plurality of series-connected submodules, each comprising a capacitor and a plurality of semiconductor switches arranged in a half-bridge or a full-bridge submodule topology; and
said semiconductor switch is one of the plurality of semiconductor switches of one of the series-connected submodules.

17. The method of claim 6, wherein said supercapacitor is one of a group of supercapacitors arranged in series.

18. A control unit comprising means for carrying out the method according to claim 3.
